(19) United States
(12) Patent Application Publication
(10) Pub. No.: US 2015/0221502 A1
(43) Pub. Date: Aug. 6, 2015

(54) EPITAXIAL WAFER AND METHOD FOR PRODUCING SAME

(71) Applicant: RIKEN, Wako-shi, Saitama (JP)

(72) Inventors: Takuya Mino, Osaka (JP); Takayoshi Takano, Saitama (JP); Kenji Tsubaki, Osaka (JP); Hideki Hirayama, Saitama (JP); Masakazu Sugiyama, Tokyo (JP)

(73) Assignee: RIKEN, Wako-shi, Saitama (JP)

(21) Appl. No.: 14/426,351

(22) PCT Filed: Mar. 8, 2013
(86) PCT No.: PCT/JP2013/001502

§ 371 Date: Mar. 5, 2015

(30) Foreign Application Priority Data
Sep. 6, 2012 (JP) 2012-196104

(51) Int. Cl. H01L 21/02; H01L 21/285

(52) U.S. Cl. CPC H01L 21/02178; H01L 21/28562; H01L 21/02271

(57) ABSTRACT

The epitaxial wafer includes a silicon substrate, an aluminum nitride thin film feeing a main surface of the silicon substrate, and an aluminum deposit between the silicon substrate and the aluminum nitride thin film so as to inhibit formation of silicon nitride. In the method for producing the epitaxial wafer, to form the aluminum deposit on the main surface of the silicon substrate, trimethyl aluminum is supplied into a reactor after a substrate temperature defined as a temperature of the silicon substrate is adjusted to a first predetermined temperature equal to or mare than. 300° C. and less than 1200° C. Thereafter, to form the aluminum nitride thin film facing the main surface of the silicon substrate, trimethyl aluminum and ammonia are supplied into the reactor after the substrate temperature is adjusted to a second predetermined temperature equal to or more than 1200° C. and equal to or less than 1400° C.

### TECHNICAL FIELD

The present invention relates to an epitaxial wafer in which an aluminum nitride thin film is on a silicon substrate, and a method for producing same.

### BACKGROUND ART

At various sites, there have been studied and developed semiconductor devices based on group III nitride semiconductors such as light emitting devices exemplified by light emitting diodes and electronic devices exemplified by HEMT (high electron mobility transistor). Recently, in various fields of use such as high efficiency white lighting, sterilization, medical treatments, and high speed treatments of environmental pollutants, ultraviolet light emitting devices based on group III nitride semiconductors are highly expected.

With regard to group III nitride semiconductor crystal, it is difficult to reduce cost and increase size of a bulk crystal (e.g., a GaN free-standing substrate and an AlN free-standing substrate) available for a substrate for epitaxial growth. Hence, group III nitride semiconductor crystal is used by being epitaxially grown on a substrate made of a different material. As for ultraviolet light emitting devices, there has been proposed using a substrate in which an aluminum nitride layer is epitaxially grown on a sapphire substrate (e.g., JP 2009-54780 A: Patent Literature 1).

However, group III nitride semiconductor crystal is greatly different in a lattice constant from the sapphire substrate. Therefore, threading dislocations may occur in group III nitride semiconductor crystal epitaxially grown on the sapphire substrate due to a difference between lattice constants of the group III nitride semiconductor crystal and the sapphire substrate. In view of this, as for the semiconductor devices, improvement of crystallinity of group III nitride semiconductor crystal and performance of the device are expected.

The sapphire substrate has very high hardness, and therefore processing (polishing) of the sapphire substrate is difficult. For this reason, as for an ultraviolet light emitting diode which is one type of ultraviolet light emitting devices, it is difficult, to subject a substrate for epitaxial growth to processing for improvement of a light-outcoupling efficiency.

Therefore, in the past, a silicon substrate has been studied as a substrate for epitaxial growth of group III nitride semiconductor crystal (e.g., JP 5-343741 A: Patent Literature 2). Processing such as fine processing and polishing of the silicon substrate is easier than that of the sapphire substrate, and the silicon substrate is superior in heat dissipation than the sapphire substrate. Currently, a large size silicon substrate is available at lower cost than a large size sapphire substrate and a large size group III nitride semiconductor crystal substrate (e.g., a GaN substrate and an AlN substrate). In view of this, techniques of growing group III nitride semiconductor crystal on a silicon substrate is considered to be important techniques in development of next generation high efficiency ultraviolet light emitting devices.

As a crystal growth method for epitaxially growing an aluminum nitride thin film on a silicon substrate, an MOVPE (metal organic vapor phase epitaxy) method can be considered in view of thickness controllability and mass productivity.

However, like the sapphire substrate, the silicon substrate is very different in a lattice constant front group III nitride semiconductor crystal. Therefore, when the silicon substrate is used as a substrate for epitaxial growth, it is difficult to form a monocrystalline group III nitride semiconductor thin film with good crystallinity on the substrate, and also it is difficult to form a monocrystalline aluminum nitride thin film with good crystallinity.

The present inventors have presumed that, in order to grow a high quality aluminum nitride thin film with good crystallinity on a silicon substrate by an MOVPE method, it is necessary to adjust a substrate temperature to 1200° C. or more in a similar manner to a ease of growth by use of a sapphire substrate.

The present inventors have repeated experiments of growing aluminum nitride thin films on silicon substrates by MOVPE methods, and evaluated surface flatness of aluminum nitride thin films with an optical microscope and an SEM (scanning electron microscope). Based on these results, the present inventor have figured out that, even when the substrate temperature is equal to or more than 1200° C., reproducibility of flatness of surfaces of aluminum nitride thin films is relatively low and in some cases there are protrusions on surfaces of aluminum nitride thin films.

### SUMMARY OF INVENTION

In view of the above insufficiency, the present invention has aimed to propose an epitaxial wafer having an improved surface flatness of an aluminum nitride thin film formed on a silicon substrate, and a method for producing same.

The epitaxial wafer of the present invention includes: a silicon substrate; an aluminum nitride thin film provided facing a main surface of the silicon substrate; and an aluminum deposit provided between the silicon substrate and the aluminum nitride thin film so as to inhibit formation of silicon nitride.

The method for producing an epitaxial wafer of the present invention is a method for producing an epitaxial wafer including a silicon substrate, an aluminum nitride thin film provided facing a main surface of the silicon substrate, and an aluminum deposit provided between the silicon substrate and the aluminum nitride thin film so as to inhibit formation of silicon nitride. The method of the present invention includes: a first step of forming the aluminum deposit on the main surface of the silicon substrate by, alter the silicon substrate is prepared and placed inside a reactor of a low pressure MOVPE device, adjusting a substrate temperature defined as a temperature of the silicon substrate to a first predetermined temperature which is equal to or more than 300° C. and less than 1200° C. and subsequently supplying trimethyl aluminum which is source gas for aluminum, into the reactor; and a second step of forming the aluminum nitride thin film facing the main surface of the silicon substrate by adjusting the substrate temperature to a second predetermined temperature which is equal to or more than 1200° C. and equal to or less than 1400° C. after the first step and subsequently supplying the trimethyl aluminum and ammonia which is source gas for nitrogen.

With regard to this method for producing an epitaxial wafer, in the first step, a deposition thickness of the aluminum deposit is more than 0.2 nm and less than 20 nm.

As for the epitaxial wafer of the present invention, it is possible to improve surface flatness of an aluminum nitride thin film formed on a silicon substrate.

As for the method for producing an epitaxial wafer of the present invention, it is possible to improve surface flatness of an aluminum nitride thin film, formed on a silicon substrate.

### BRIEF DESCRIPTION OF THE DRAWINGS

FIG. 1 is a schematic section illustrating the epitaxial wafer of the embodiment.

FIG. 2A is a bird's eye SEM image illustrating the silicon substrate after annealed at the substrate temperature of 1300° C. under the H₂ gas atmosphere.

FIG. 2B is a sectional SEM image illustrating the silicon substrate after annealed at the substrate temperature of 1300° C. under the H₂ gas atmosphere.

FIG. 2C is a bird's eye SEM image illustrating the silicon substrate after annealed at the substrate temperature of 1200° C. under the H₂ gas atmosphere.

FIG. 2D is a sectional SEM image illustrating the silicon substrate after annealed at the substrate temperature of 1200° C. under the H₂ gas atmosphere.

FIG. 3 shows a result of observation on the surface of the aluminum nitride thin film of Comparative Example with an optical microscope.

FIG. 4 shows a result of observation on the surface of the aluminum nitride thin film based on the epitaxial wafer of Example 1 with an optical microscope.

FIG. 5A shows a result of observation on the surface of the aluminum nitride thin film of Example 2 with an optical microscope.

FIG. 5B shows a result of observation on the surface of the aluminum nitride thin film based on the epitaxial wafer of Example 1 with an optical microscope.

FIG. 5C shows a result of observation on the surface of the aluminum nitride thin film of Example 3 with an optical microscope.

### DESCRIPTION OF EMBODIMENTS

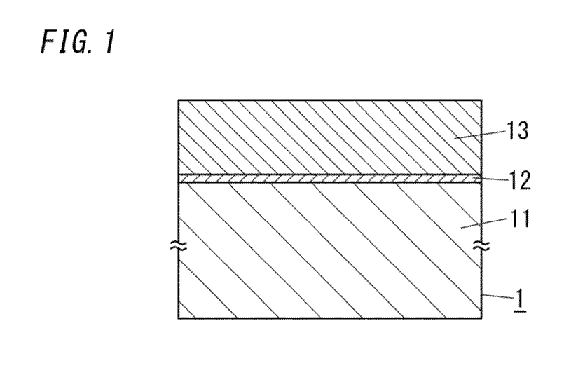

Hereinafter, the epitaxial wafer 1 of the present embodiment is described with reference to FIG. 1.

The epitaxial wafer 1 includes: a silicon substrate 11; an aluminum nitride thin film 13 provided facing a main surface of the silicon substrate 11; and an aluminum deposit 12 provided between the silicon substrate 11 and the aluminum nitride thin film 13 so as to inhibit formation of silicon nitride.

The aluminum deposit 12 and the aluminum nitride thin film 13, which is of a group III nitride semiconductor crystal, are formed by use of a low pressure MOVPE device.

The epitaxial wafer 1 is available for producing a semiconductor device made by use of group III nitride semiconductors. For example, the epitaxial wafer 1 is available for producing an ultraviolet light emitting diode. In this case, multiple ultraviolet light emitting diodes can be formed by use of the epitaxial wafer 1 based on a wafer size and a chip size of ultraviolet light emitting diodes. In this use, the epitaxial wafer 1 can cause an increase in crystallinity of a group III nitride semiconductor layer to be formed on the epitaxial wafer 1.

In a ease of producing ultraviolet light emitting diodes, for example, a first nitride semiconductor layer of a first conductivity type is formed directly or indirectly on the epitaxial wafer 1. Then, a light emitting layer made by use of AlGaN-based material is formed on an opposite side of the first nitride semiconductor layer from the epitaxial wafer 1. Thereafter, a second nitride semiconductor layer of a second conductivity type is formed on an opposite side of the light emitting layer from the first nitride semiconductor layer. Subsequently, a first electrode is formed to be electrically connected to the first nitride semiconductor layer, and a second electrode is formed to be electrically connected to the second nitride semiconductor layer. In this example, the first nitride semiconductor layer, the light emitting layer, and the second nitride semiconductor layer constitute the group III nitride semiconductor layer on the epitaxial wafer 1. This group III nitride semiconductor layer may be formed by use of a low pressure MOVPE device, for example. Therefore, the aluminum deposit 12, the aluminum nitride thin film 13, and the group III nitride semiconductor layer can he made by use of the same low pressure MOVPE device. The first electrode and the second electrode can be made by use of a deposition device, for example.

The light emitting layer preferably has a quantum well structure. The quantum well structure may be a multiple quantum well structure or a single quantum well structure. As for the light emitting layer, to obtain ultraviolet light of a desired emission wavelength, an atomic ratio of Al in a well layer is selected. With regard to the light emitting layer made of AlGaN-based material, by changing the atomic ratio of Al, it is possible to select the desired emission wavelength from an emission wavelength (emission peak wavelength) range of 210 to 360 nm. For example, when the desired emission wavelength is about 265 nm, the atomic ratio of Al is set to 0.50. Alternatively, in the ultraviolet light emitting diode, the light emitting layer may be a single structure, and a double hetero-structure may be constituted by the light emitting layer and layers (e.g., n-type nitride semiconductor layers and p-type nitride semiconductor layers) on opposite sides of the light emitting layer in the thickness direction of the light emitting layer.

When the first conductivity type is n-type, the first nitride semiconductor layer is an n-type nitride semiconductor layer. The n-type nitride semiconductor layer serves to transfer electrons to the light emitting layer. The thickness of the n-type nitride semiconductor layer may be 2 μm as one example, but is not limited particularly. Further, the n-type nitride semiconductor layer is an n-type AlₓGa₁₋ₓN (0<x<1) layer. In this regard, x which indicates the atomic ratio of Al in the n-type AlₓGa₁₋ₓN (0<x<1) layer serving as the n-type nitride semiconductor layer is not limited particularly as long as the n-type nitride semiconductor layer does not absorb ultraviolet light emitted from the light emitting layer. Note that, material of the n-type nitride semiconductor layer is not limited to AlGaN, but may be AlInN, AlGaInN, or the like, as long as the n-type nitride semiconductor layer does not absorb ultraviolet light emitted from the light emitting layer.

When the second conductivity type is p-type, the second nitride semiconductor layer is a p-type nitride semiconductor layer. The p-type nitride semiconductor layer serves to transfer holes to the light emitting layer. Further, the p-type nitride semiconductor layer is a p-type Al_{y}Ga_{1-y}N (0<x<1) layer. In this regard, y which indicates the atomic ratio of Al in the p-type Al_{y}Ga_{1-y}N (0<y<1) layer serving as the p-type nitride semiconductor layer is not limited particularly as long as the p-type nitride semiconductor layer does not absorb ultraviolet light emitted from the light emitting layer. The thickness of the p-type nitride semiconductor layer may be equal to or less than 200 nm preferably, and be equal to or less than 100 nm more preferably.

Hereinafter, each component of the epitaxial wafer 1 is described in detail.

The silicon substrate 11 is a monocrystalline silicon substrate whose crystal structure is a diamond structure. The monocrystalline silicon substrate may be a silicon wafer of about 50 to 300 mm in diameter and about 200 to 3000 μm in thickness, for example. The conductivity type of the silicon substrate 11 may be any of p-type and n-type. Further, the resistivity of the silicon substrate 11 is not limited particularly.

It is preferable that an opposite surface of the aluminum nitride thin film 13 from the silicon substrate 11 be a (0001) surface. In this regard, to obtain the aluminum nitride thin film 13 with excellent crystallinity by epitaxial growth, in view of lattice matching with the aluminum nitride thin film 13, it is preferable that the silicon substrate 11 be a monocrystalline silicon substrate in which the main surface is a (111) surface.

In the silicon substrate 11, an off-angle from a (111) surface is in a range of 0 to 0.3°, preferably. In this case, in the process of forming the aluminum deposit 12 on the main surface of the silicon substrate 11, it is possible to inhibit multiple aluminum nuclei from being formed like islands, and therefore it is possible to form the aluminum deposit 12 in a continuous film like layer or in a substantially continuous film. As a result, the epitaxial wafer 1 can contribute improvement of quality of the aluminum nitride thin film 13. This is probably because atoms supplied to form the aluminum deposit 12 are dispersed on the main surface of the silicon substrate 11 and are deposited at stable sites and a decrease in the off-angle of the silicon substrate 11 causes an increase in a terrace width and a decrease in a density of nuclei.

The present inventors focused on studying for a reason why the aluminum nitride thin film 13 with good flatness is not formed with regard to a substrate temperature of equal to or more than 1200° C. in a case where the aluminum nitride thin film 13 is directly formed on the silicon substrate 11 by use of the low pressure MOVPE device. As part of the study, the present inventors conducted an experiment in which silicon substrate 11 is placed inside a reactor of the low pressure MOVPE device and is annealed at the substrate temperature of equal to or more than 1200° C. for various annealing time under a condition only H₂ gas is supplied. The present inventors observed the annealed silicon substrates 11 taken out from the low pressure MOVPE device with an optical microscope and SEM. Based on results of observation with the optical microscope, the present inventors found many black spots on the main surface of the silicon substrate 11. To identify what the spots are, the present inventors conducted observation with SEM on the annealed silicon substrates 11. Based on results of the observation with SEM, the present inventors figured out that the aforementioned spots are protrusions.

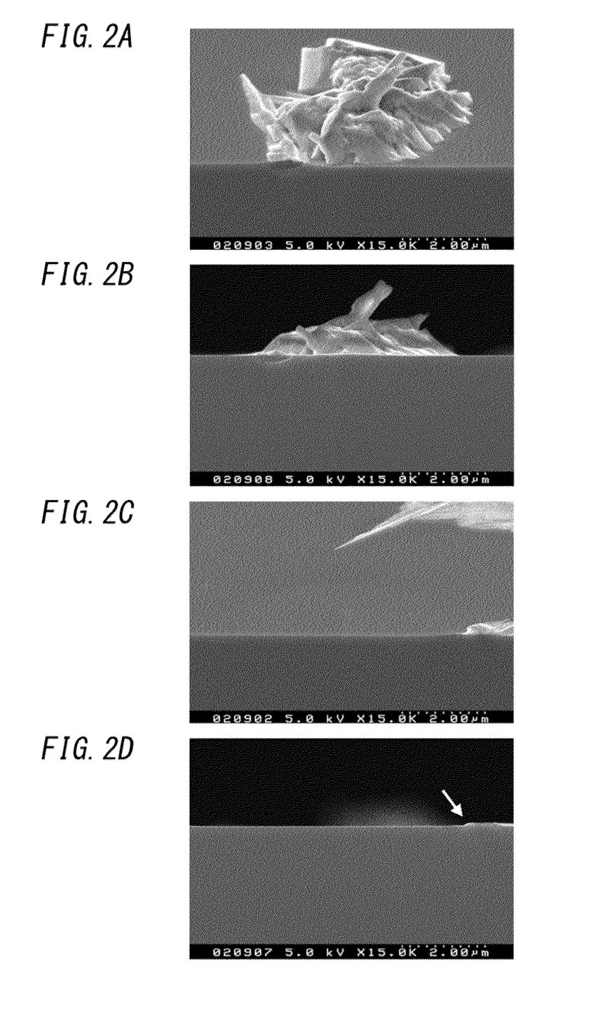

Some of the annealed silicon substrates 11 have protrusions of about 1 to 2 μm in height and some of the annealed silicon substrates 11 have protrusions of about 0.1 to 0.2 μm in height. Based on the results of the aforementioned experiment, the present inventors figured out that an increase in the substrate temperature causes an increase in the height of the protrusion and an increase in the annealing time causes an increase in the height of the protrusion. Further, based on the results of the aforementioned experiment, the present inventors figured out that the height of the protrusions formed on the main surface of the silicon substrate 11 was not less than 0.1 μm. FIG. 2A, and FIG. 2B are SEM images of the silicon substrate 11 on which protrusions of about 1 to 2 μm in height are formed. FIG. 2C, and FIG. 2D are SEM images of the silicon substrate 11 on which protrusions of about 0.1 to 1 μm in height are formed.

To examine the composition of the protrusions formed on the silicon substrate 11, the present inventors conducted a composition analysis based on an EDX method (energy dispersive X-ray spectroscopy). The result of the composition analysis based on the EDX method shows that the protrusion is mainly constituted by silicon and nitrogen. The present inventors presumed that the cause of occurrence of protrusions is that ammonia remaining inside the reactor of the low pressure MOVPE device reacts with constituents of the silicon substrate 11 at a high temperature of not less than 1200° C. to give silicon nitride.

Further, the present inventors presumed that these protrusions inhibit epitaxial growth of the group III nitride semiconductor layer to he formed on the aluminum nitride thin film 13 and cause decreases in a performance and a yield of a semiconductor device including the group III nitride semiconductor layer.

To inhibit silicon nitride from being formed on the main surface of the silicon substrate 11 and to enable formation of the aluminum nitride thin film 13 which is high quality and monocrystalline, the present inventors has conceived to provide the aluminum deposit 12 between the silicon substrate 11 and the aluminum nitride thin film 13. In other words, the aluminum deposit 12 is provided as a layer of inhibiting formation of SiN.

It is preferable that a deposition thickness of the aluminum deposit 12 be greater than 0.2 nm and less than 20 nm. In this regard, the deposition thickness of the aluminum deposit 12 is a value obtained by multiplying a deposition speed of the aluminum deposit 12 preliminarily calculated by experiments by the deposition time of the aluminum deposit 12. In this regard, to calculate the deposition speed, the aluminum deposit 12 formed on the silicon substrate 11 to be relatively thick was observed with SEM. The deposition speed is a value calculated by dividing a thickness of the aluminum deposit 12 measured from a sectional SEM image by the deposition time of the aluminum deposit 12.

When the deposition thickness of the aluminum deposit 12 is less than 0.2 nm, formation of the aluminum deposit 12 may cause forma lion of silicon nitride on the main surface of the silicon substrate 11. This is presumably because the aluminum deposit 12 is a discontinuous film like islands and therefore, in a process of increasing the substrate temperature to a growth temperature of the aluminum nitride thin film 13 under supply of H₂ gas after the formation of the aluminum deposit 12, constituents of the silicon substrate 11 may react with ammonia (NH₂) remaining inside the reactor or atoms of nitrogen deposited from reaction products (nitride semiconductors) adhering to heated surrounding members (e.g., a susceptor for holding the silicon substrate 11 and a member for providing a path for a flow of source gas).

When the deposition thickness of the aluminum deposit 12 is greater than 20 nm, this may cause a decrease in surface flatness of the aluminum nitride thin film 13. This is presumably because the substrate temperature for forming the aluminum nitride thin film 13 is equal to or more than 1200° C. and therefore the surface flatness of the aluminum deposit 12 may decrease before formation of the aluminum nitride thin film 13.

The aluminum nitride thin film 13 may also be used as a buffer layer for decreasing the threading dislocation of the nitride semiconductor layer to be formed thereon and for decreasing the residual strain of the nitride semiconductor layer. The aluminum nitride thin film 13 is formed by use of the aforementioned low pressure MOVPE device so as to cover the aluminum deposit 12 on the main surface of the silicon substrate 11. In a process of growing the aluminum nitride thin film 13, source gas for aluminum and source gas for nitrogen are supplied into the reactor of the low pressure MOVPE device. The source gas for aluminum is TMA (trimethyl aluminum), for example. TMA has a decomposition temperature of 300° C. The source gas for nitrogen is NH₃, for example.

It is preferable that the aluminum nitride thin film 13 have a thickness in a range of 100 nm to 10 μm, for example. In view of the surface flatness, the thickness of the aluminum nitride thin film 13 may be preferably equal to or more than 100 nm. Further, in view of prevention of occurrence of cracks caused by lattice mismatch, the thickness of the aluminum nitride thin film 13 may be preferably equal to or less than 10 μm.

Note that, the aluminum nitride thin film 13 may contain impurities such as H, C, O, Si, and Fe which are unavoidably contained in the aluminum nitride thin film 13 in the process of forming the aluminum nitride thin film 13. The aluminum nitride thin film 13 may contain impurities Si, Ge, Be, Mg, Zn, and C which are added purposely for controlling conductivity.

Hereinafter, the method of producing the epitaxial wafer 1 of the present embodiment is described.

(1) Step of introducing the silicon substrate 11 into the reactor

In this step, the silicon substrate 11 having a (111) surface as the main surface is introduced into the reactor of the low pressure MOVPE device. In this step, it is preferable that the silicon substrate 11 be subjected to pretreatment with chemicals to purify surfaces of the silicon substrate 11 before the silicon substrate 11 is introduced into the reactor. In the pretreatment, organic substances are removed with sulfate reduction, and then oxides are removed with hydrofluoric acid, for example. Additionally, in this step, after the silicon substrate 11 is introduced into the reactor, an inside of the reactor is evacuated. Thereafter, the inside of the reactor may be filled with N₂ gas by supplying N₂ gas or the like into the reactor, and then evacuated.

(2) Step of forming the aluminum deposit 12 (first step)

In this step, a pressure inside the reactor is decreased down to a first predetermined pressure, and then the substrate temperature defined as the temperature of the silicon substrate 11 is increased up to a first predetermined temperature for depositing the aluminum deposit 12 while the pressure of the reactor is kept to a prescribed pressure. In this step, thereafter, the aluminum deposit 12 is formed on the main surface of the silicon substrate 11 by supplying TMA serving as the source gas for aluminum and H₂ gas serving as carrier gas into the reactor for only first predetermined time under a condition where the pressure inside the reactor is kept to the first predetermined pressure and the substrate temperature is kept to the first predetermined temperature. For example, the first predetermined pressure may be 10 kPa≈76 Torr. However, the first predetermined pressure is not limited to this and may be set to a pressure in a range of about 1 kPa to 40 kPa. The first predetermined temperature may be set to 900° C., for example. However, the first predetermined temperature is not limited to this and may be preferably set to a temperature equal to or more than 300° C. and less than 1200° C. This is because, when the substrate temperature is less than 1200° C., it is possible to prevent reaction of constituents of the silicon substrate 11 with remaining NH₃ under a high temperature equal to or more than 1200° C. and thereby occurrence of protrusions of silicon nitride can be suppressed. Further, this is because, when the substrate temperature is set to 300° C., TMA is decomposed and therefore atoms of aluminum reaches the silicon substrate 11 alone to form the aluminum deposit 12. It is more preferable that the first predetermined temperature be in a temperature range of 500° C. to 1150°. This is because, when the substrate temperature is more than 1150° C., the substrate temperature is likely to overshoot or vary toward a high temperature side and thereby become equal to or more than 1200° C. Further, this is because, when the substrate temperature is equal to or more than 500° C., decomposition efficiency of TMA can be improved so as to be approximately 100%, The first predetermined time may be set to 6 seconds, for example. However, the first predetermined time is not limited to this and may be preferably set to be in a range of 3 seconds to 20 seconds. In this step, it is preferable that a concentration of TMA to H₂ gas serving as the carrier gas be equal to or more than 0.010 μmol/L and be equal to or less than 1.0 μmol/L, for example. When the concentration of TMA is less than 0.010 μmol/L, aluminum is unlikely to spread to the entire main surface of the silicon substrate 11, and therefore in some regions of the main surface the aluminum deposit 12 may not be present and some parts of the aluminum deposit 12 may have small deposition thickness. As a result, protrusions of silicon nitride are likely to be formed before formation of the aluminum nitride thin film 13. In contrast, when the concentration of TMA is more than 1.0 μmol/L, the surfaces of the aluminum deposit 12 may become rough, and therefore the surfaces of the aluminum nitride thin film 13 formed thereon also may become rough.

Note that, in the method of producing the epitaxial wafer 1, the substrate temperature of the silicon substrate 11 introduced inside the reactor is increased up to a predetermined heat treatment temperature (e.g., 900° C.) before the first step, and the main surface of the silicon substrate 11 is purified by heating at this heat treatment temperature. In this case, the silicon substrate 11 is heated, under a condition where H₂ gas is supplied info the reactor, and therefore purification can be conducted effectively.

(3) Step of forming the aluminum nitride thin film. 13 (second step)

This step is subsequent to the first step and is a step of forming the aluminum nitride thin film 13 facing the main surface of the silicon substrate 11 by supplying TMA and NH₃ serving as the source gas for nitrogen into the reactor after the substrate temperature is adjusted to a second predetermined temperature which is equal to or more than 1200° C. and is equal to or less than 1400° C.

In more detail, in this step, the substrate temperature of the silicon substrate 11 is set to the second predetermined temperature. To form the aluminum nitride thin film 13 which is less defective and is high quality, the second predetermined temperature is set to 1300° C. However, the second predetermined temperature is not limited to this and may be preferably set to a temperature equal to or more than 1200° C. and equal to or less than 1400° C., and be more preferably set to be in a range 1250 to 1350° C. In this step, when the substrate temperature is less than 1200° C., it is difficult to form the aluminum nitride thin film 13 which is less defective and is high quality. Further, in this step, when the substrate temperature is a high temperature more than 1400° 0C., surfaces of an aluminum nitride thin film become rough and thus the flatness may deteriorate.

In this step, for example, the substrate temperature is increased from the first predetermined temperature up to the second predetermined temperature while only H₂ gas is supplied into the reactor and the pressure inside the reactor is kept to a second predetermined pressure. The second predetermined pressure may be preferably equal to the first predetermined pressure but may be different from the first predetermined pressure. In this step, thereafter the aluminum nitride thin film 13 is formed (epitaxial growth is conducted) by supplying TMA serving as a source of aluminum, H₂ gas serving as carrier gas for TMA and NH₃ serving as a source of nitrogen into the reactor while the substrate temperature is kept to the second predetermined temperature.

In this step, a growth method of conducting epitaxial growth of the aluminum nitride thin film 13 by supplying TMA and NH₃ simultaneously (hereinafter, referred to as “simultaneous supply growth method”) is employed. In this step, as an alternative to the simultaneous supply growth method, a growth method of conducting epitaxial growth of the aluminum nitride thin film 13 by supplying TMA and NH₃ at different timings (hereinafter, referred to as “alternate supply growth method”) may be employed, for example. Alternatively, in this process, the simultaneous supply growth method and the alternate supply growth method may be performed at different timings. Alternatively, in this process, a growth method of the growth by supplying TMA continuously and supplying NH₃ intermittently (hereinafter, referred to as “pulse supply growth method”) may be employed. Alternatively, the simultaneous supply growth method and the pulse supply growth method may be performed at different timings. A V/III ratio indicative of a mole ratio of NH₃ to TMA may be preferably equal to or more than 1 and be equal to or less than 5000 in each of the simultaneous supply growth method, the alternate supply growth method, and the pulse supply growth method. The value of the prescribe pressure (growth pressure) in this step is only example and is not limited particularly. Note that, it is considered that parameters changing the surface flatness of the aluminum nitride thin film 13 may include the V/III ratio, the supply amount of TMA, and the growth pressure in addition to the substrate temperature. However, the substrate temperature is probably an essential parameter.

After the silicon substrate 11 is introduced into the reactor of the low pressure MOVPE device In the aforementioned step (1), the first and second steps are conducted sequentially in the reactor of the low pressure MOVPE device until the end of the step (3). Thereby, the epitaxial wafer 1 is produced. When the thus-obtained epitaxial wafer 1 is immediately used for producing ultraviolet light emitting diodes, the epitaxial wafer 1 is left in the low pressure MOVPE device, and the group III nitride semiconductor layers including the first nitride semiconductor layer, the light emitting layer, and the second nitride semiconductor layer which are described above are sequentially stacked on the epitaxial wafer 1, and thereafter the substrate temperature is decreased down to about room temperature, and finally the epitaxial wafer 1 is taken out from the low pressure MOVPE device.

The epitaxial wafer 1 of the present embodiment described above includes the silicon substrate 11; the aluminum nitride thin film 13 provided facing the main surface of the silicon substrate 11; and the aluminum deposit 12 provided between the silicon substrate 11 and the aluminum nitride thin film 13 so as to inhibit formation of silicon nitride. Due to this configuration, in the epitaxial wafer 1, silicon nitride can be inhibited from being formed on the main surface of the silicon substrate 11 before formation of the aluminum nitride thin film 13. Consequently, it is possible to improve the surface flatness of the aluminum nitride thin film 13 formed on the silicon substrate 11.

Further, the method for producing the epitaxial wafer 1 of the present embodiment includes the first step and the second step which are conducted sequentially after the silicon substrate 11 is prepared and placed inside the reactor of the low pressure MOVPE device. The first step is a step of forming the aluminum deposit 12 on the main surface of the silicon substrate 11 by adjusting the substrate temperature defined as a temperature of the silicon substrate 11 to the first predetermined temperature which is equal to or more than 300° C. and is less than 1200° C. and subsequently supplying TMA serving as source gas for aluminum, into the reactor. The second step is a step of forming the aluminum nitride thin film 13 facing the main surface of the silicon substrate 11 by adjusting the substrate temperature of the silicon substrate 11 to the second predetermined temperature which is equal to or more than 1200° C. and is equal to or less than 1400° C. and subsequently supplying TMA and NH₃ serving as source gas for nitrogen. Consequently, the method for producing the epitaxial wafer 1 of the present embodiment includes the first step prior to the second step. Therefore, it is possible to prevent silicon nitride from being formed on the main surface of the silicon substrate 11, and thus the surface flatness of the aluminum nitride thin film 13 to be formed on the silicon substrate 11 can be improved.

In the method for producing the epitaxial wafer 1 of the present embodiment, it is preferable that, in the first step, the deposition thickness of the aluminum deposit 12 be more than 0.2 nm and less than 20 nm. Consequently, in the method for producing the epitaxial wafer 1, it is possible to improve the surface flatness of the aluminum nitride thin film 13 formed on the silicon substrate 11. Additionally, it is preferable that, in the first step, the concentration of TMA to H₂ gas serving as carrier gas be equal to or more than 0.010 μmol/L and equal to or less than 1.0 μmol/L. Consequently, in the method for producing the epitaxial wafer 1, it is possible to improve the surface flatness of the aluminum nitride thin film 13 formed on the silicon substrate 11.

### Example 1

In Example 1, the epitaxial wafer 1 was produced in accordance with the method for producing the epitaxial wafer 1 explained in context regarding the present embodiment.

The silicon substrate 11 is a silicon wafer in which the conductivity type is n-type, a specific resistance is in a range of 1 to 3 Ωcm, a thickness is 430 μm, and the main surface is a (111) surface.

As the pretreatment prior to the introduction of the silicon substrate 11 into the low pressure MOVPE device, organic substances were removed with sulfate reduction, and then oxides were removed with hydrofluoric acid. After the silicon substrate 11 was introduced into the reactor, the reactor was evacuated, and subsequently the pressure inside the reactor was decreased down to the first predetermined pressure of 10 kPa. Thereafter, the substrate temperature was increased up to the first predetermined temperature of 900° C. while the pressure inside the reactor was kept to the first predetermined pressure. In the first step, TMA and H₂ gas were supplied into the reactor for the first predetermined time of 6 seconds while the pressure inside the reactor was kept to the first predetermined pressure and the substrate temperature was kept to 900° C. Thereby, the aluminum deposit 12 was formed on the main surface of the silicon substrate 11. In the first step of forming the aluminum deposit 12, the flow rate of TMA was set to 0.02 L/min in the standard state, that is, 20 SCCM (standard cc per minute), and the flow rate of H₂ gas was set to 100 L/min in the standard state, that is, 100 SLM (standard liter per minute). In this regard, the concentration of TMA to H₂ gas was 0.28 μmol/L.

After the aluminum deposit 12 was formed, the substrate temperature was increased up to the second predetermined temperature of 1300° C., and thereafter TMA, H₂ gas, and NH₃ were supplied into the reactor while the pressure inside the reactor was kept to the second predetermined pressure (10 kPa) equal to the first predetermined pressure and the substrate temperature was kept to 1300° C. Thereby, the aluminum nitride thin film 13 of about 300 nm in thickness was formed. In the second step of forming the aluminum nitride thin film 13, the flow rate of TMA was set to 0.1 L/min in the standard state, the flow rate of H₂ gas was set to 100 L/min in the standard state, and the flow rate of NH₃ was set to 1 L/min in the standard state.

### Comparative Example

In Comparative Example, the silicon substrate 11 which was according to the same specification as Example 1 was prepared. The pretreatment prior to introduction of the silicon substrate 11 into the low pressure MOVPE device was same as that of Example 1. After the silicon substrate 11 was introduced into the reactor, the reactor was evacuated, and subsequently the pressure inside the reactor was decreased down to the second predetermined pressure (10 kPa) and then the substrate temperature was increased up to the second predetermined temperature of 1300° C. while the pressure inside the reactor was kept to the second predetermined pressure. Thereby, the aluminum nitride thin film 13 was formed under the same condition as Example 1.

### Example 2

In Example 2, the silicon substrate 11 which was according to the same specification as Example 1 was prepared. The pretreatment prior to introduction of the silicon substrate 11 into the low pressure MOVPE device was same as that of Example 1. After the silicon substrate 11 was introduced into the reactor, the reactor was evacuated, and subsequently the pressure inside the reactor was decreased down to the first predetermined pressure (10 kPa). Thereafter, the substrate temperature was increased up to the first predetermined temperature of 900° C. while the pressure inside the reactor was kept to the first predetermined pressure. In the first step, TMA and H₂ gas were supplied into the reactor for the first predetermined time of 6 seconds while the pressure inside the reactor was kept to the first predetermined pressure and the substrate temperature was kept to 900° C. Thereby, the aluminum deposit 12 was formed on the main surface of the silicon substrate 11. In the first step of forming the aluminum deposit 12, the flow rate of TMA was set to 0.0007 L/min in the standard state, that is, 0.7 SCCM, and the flow rate of H₂ gas was set to 100 L/min in the standard state, that is, 100 SLM. In this regard, the concentration of TMA to H₂ gas was 0.0098 μmol/L. Note that, this deposition condition of the aluminum deposit 12 corresponds to the deposition thickness of 0.2 nm.

After the aluminum deposit 12 was formed, the substrate temperature was increased up to the second predetermined temperature of 1300° C., and thereafter the aluminum nitride thin film 13 was formed under the same condition as Example 1.

### Example 3

In Example 3, the silicon substrate 11 which was according to the same specification as Example 1 was prepared. The pretreatment prior to introduction of the silicon substrate 11 into the low pressure MOVPE device was same as that of Example 1. After the silicon substrate 11 was introduced into the reactor, the reactor was evacuated, and subsequently the pressure inside the reactor was decreased down to the first predetermined pressure (10 kPa). Thereafter, the substrate temperature was increased up to the first predetermined temperature of 900° C. while the pressure inside the reactor was kept to the first predetermined pressure. In the first step, TMA and H₂ gas were supplied into the reactor for the first predetermined time of 6 seconds while the pressure inside the reactor was kept to the first predetermined pressure and the substrate temperature was kept to 900° C. Thereby, the aluminum deposit 12 was formed on the main surface of the silicon substrate 11. In the first step of forming the aluminum deposit 12, the flow rate of TMA was set to 0.08 L/min in the standard state, that is, 80 SCCM, and the flow rate of H₂ gas was set to 100 L/min in the standard state, that is, 100 SLM. In this regard, the concentration of TMA to H₂ gas was 1.1 μmol/L. Note that, this deposition condition of the aluminum deposit 12 corresponds to the deposition thickness of 20 nm.

After the aluminum deposit 12 was formed, the substrate temperature was increased up to the second predetermined temperature of 1300° C., and thereafter the aluminum nitride thin film 13 was formed under the same rendition as Example 1.

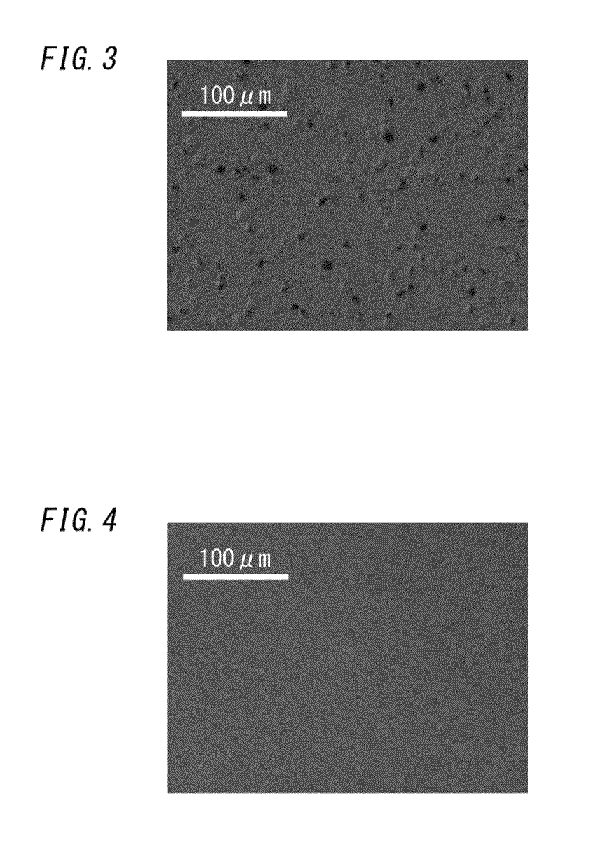

As shown in FIG. 3, the observation on the surface of the aluminum nitride thin film 13 on the silicon substrate 11 produced according to the production method of Comparative Example with an optical microscope shows there are many black spots. The observation result with SEM shows that these spots are protrusions of equal to or more than 0.1 μm in height. Further, the result of composition analysis with EDX shows that the main components of the protrusion are silicon and nitrogen. In contrast, the result of observation with an optical microscope shows that the surface of the aluminum nitride thin film 13 on the silicon substrate 11 produced according to the production method of Example 1 is a mirror surface as shown in FIG. 4.

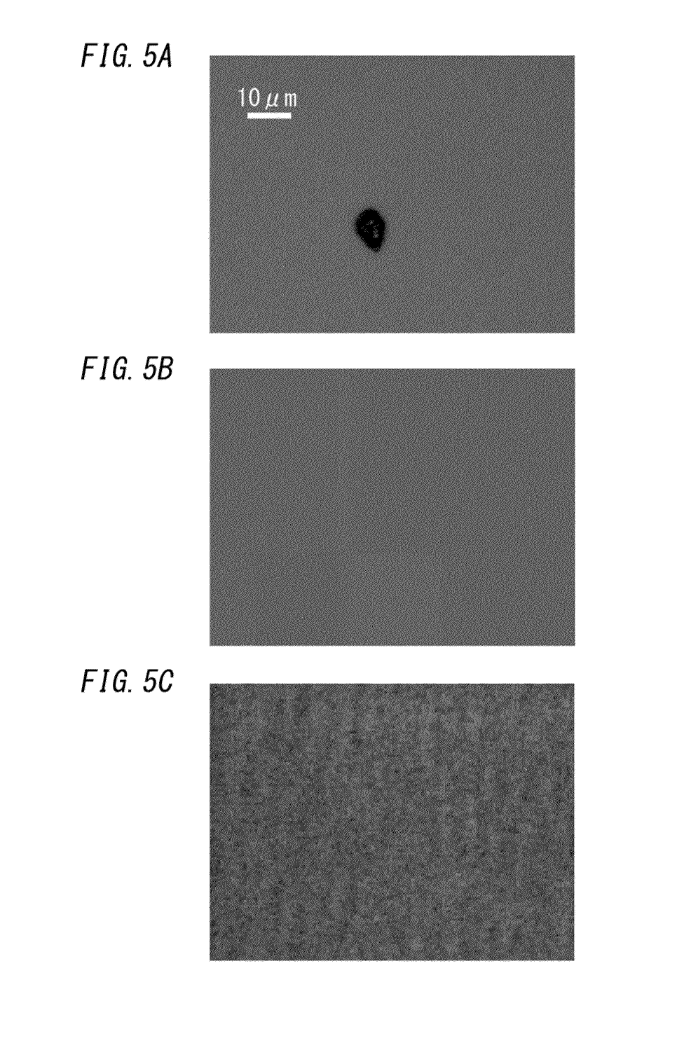

FIGS. 5A, 5B, and 5C show results of observations on surfaces of the aluminum nitride thin, films 13 formed based on Example 2, Example 1, and Example 3 with an optical microscope, respectively.

As shown in FIG. 5A, protrusions (black spots) are observed on the surface of the aluminum nitride thin film 13 of Example 2. In contrast, the surface of the aluminum nitride thin film 13 of Example 1 is a mirror surface as shown in FIG. 5B, and there is no protrusion on the surface. Note that, the number of the protrusions on the surface of the aluminum nitride thin film 13 of Example 2 is ten with regard to the entire surface of the aluminum nitride thin film 13. In view of this, it is presumed that in Example 2 formation of silicon nitride is drastically suppressed relative to Comparative Example 1. Therefore, if is preferable that the concentration of TMA to H₂ gas in the first step be equal to or more than 0.010 μmol/L.

As shown in FIG. 5C, no protrusion is observed on the surface of the aluminum nitride thin film 13 of Example 3, but the surface is somewhat rough. The reason why the surface of the aluminum nitride thin film 13 is rough is probably that the surface of the aluminum deposit 12 excessively deposited on the surface of the silicon substrate 11 is roughened due to heating to the substrate temperature in the second step. Therefore, it is preferable that the concentration of TMA to H₂ gas in the first step be equal to or less than 1.0 μmol/L.

1. An epitaxial wafer, comprising:
a silicon substrate;
an aluminum nitride thin film provided facing a main surface of the silicon substrate; and
an aluminum deposit provided between the silicon substrate and the aluminum nitride thin film so as to inhibit formation of silicon nitride.

2. A method for producing an epitaxial wafer, the epitaxial wafer including a silicon substrate, an aluminum nitride thin film provided facing a main surface of the silicon substrate, and an aluminum deposit provided between the silicon substrate and the aluminum nitride thin film so as to inhibit formation of silicon nitride,
the method comprising:
a first step of forming the aluminum deposit on the main surface of the silicon substrate by, after the silicon substrate is prepared and placed inside a reactor of a low pressure MOVPE device, adjusting a substrate temperature defined as a temperature of the silicon substrate to a first predetermined temperature which is equal to or more than 300° C. and less than 1200° C. and subsequently supplying trimethyl aluminum which is source gas for aluminum, into the reactor; and
a second step of forming the aluminum nitride thin film facing the main surface of the silicon substrate by adjusting the substrate temperature to a second predetermined temperature which is equal to or more than 1200° C. and equal to or less than 1400° C. after the first step and subsequently supplying the trimethyl aluminum and ammonia which is source gas for nitrogen.

3. The method for producing an epitaxial wafer, according to claim 2, wherein
in the first step, a deposition thickness of the aluminum deposit is more than 0.2 nm and less than 20 nm.
